(19) United States
(12) Patent Application Publication
(10) Pub. No.: US 2016/0336143 A1
(43) Pub. Date: Nov. 17, 2016

(54) CHARGED PARTICLE BEAM APPARATUS AND METHOD OF CALIBRATING SAMPLE POSITION

(71) Applicant: Kabushiki Kaisha Toshiba, Minato-ku (JP)

(72) Inventor: Takashi ISHII, Yokohama (JP)

(73) Assignee: Kabushiki Kaisha Toshiba, Minato-ku (JP)

(21) Appl. No.: 15/066,536

(22) Filed: Mar. 10, 2016

Related U.S. Application Data
(60) Provisional application No. 62/162,050, filed on May 15, 2015.

(51) Int. Cl. H01J 37/20; H01J 37/244; H01J 37/28

(52) U.S. Cl. CPC H01J 37/20; H01J 37/28; H01J 37/244; H01J 2237/20214; H01J 2237/20285

(57) ABSTRACT

In accordance with an embodiment, a charged particle beam apparatus includes an irradiating section, a detecting section, a range setting section, a scanning control section, a control section, and a sample position calibrating section. The range setting section sets a scanning range of a charged particle beam. The scanning control section scans the set scanning range with the charged particle beam. The control section relatively rotates the sample by each predetermined unit in association with an entering direction of the charged particle beam, detects peak values of the signal from the detecting section when the scanning range is scanned by each rotating angle with the charged particle beam, specifies the rotating angle corresponding to the maximum peak value among the peak values of the respective detected rotating angles, and specifies a reference position to observe the sample on the basis of the specified rotating angle.

### CROSS REFERENCE TO RELATED APPLICATIONS

This application is based upon and claims the benefit of U.S. provisional Application No. 62/162,050, filed on May 15, 2015, the entire contents of which are incorporated herein by reference.

### FIELD

Embodiments described herein relate generally to a charged particle beam apparatus and a method of calibrating a sample position.

### BACKGROUND

When a semiconductor device is manufactured, it is important to carry out performance management of the semiconductor device by measuring a device structure such as a dimension of a pattern or a taper angle of a side wall.

A scanning electron microscope (hereinafter referred to as “the SEM”) is used in such measurement of the device structure.

More specifically, the device structure is observed by processing a structure taken out of a wafer by cutting the wafer to prepare a sample, attaching the sample to a sample stage of the SEM, irradiating a cut surface with an electron beam, and then acquiring a sample image from a signal detected in accordance with secondary electrons and the like generated from the sample.

However, when the sample surface which is an observation object is not perpendicularly irradiated with the electron beam, the secondary electrons and the like generated from a sample surface other than the observation object are detected together with the secondary electrons and the like from the sample surface of the observation object. In consequence, a boundary of the structure becomes obscure in the obtained sample image, which causes an error in the dimension measurement or the like of the structure.

### BRIEF DESCRIPTION OF THE DRAWINGS

In the accompanying drawings:

FIG. 1 is one example of a block diagram showing a schematic constitution of a charged particle beam apparatus according to one embodiment;

FIG. 2 is one example of a front view showing one example of a sample;

FIG. 3 is one example of a perspective view showing an example where the sample is attached to a stage;

FIG. 4A to FIG. 5B are examples of a view to explain a method of obtaining an angle to give a signal intensity of a maximum peak in both-sides calibration (two-points irradiation); and

FIG. 6A and FIG. 6B are examples of a view to explain a method of obtaining an angle to give a signal intensity of a maximum peak in one-side calibration (one-point irradiation).

### DETAILED DESCRIPTION

In accordance with an embodiment, a charged particle beam apparatus includes an irradiating section, a detecting section, a range setting section, a scanning control section, a control section, and a sample position calibrating section. The irradiating section irradiates a sample with a charged particle beam. The detecting section outputs a signal corresponding to charged particles generated from the sample. The range setting section sets a scanning range of the charged particle beam. The scanning control section scans the set scanning range with the charged particle beam. The control section relatively rotates the sample by each predetermined unit in association with an entering direction of the charged particle beam, detects a peak value of the signal from the detecting section when the scanning range is scanned by each rotating angle with the charged particle beam, specifies the rotating angle corresponding to the maximum peak value among the peak values of the respective detected rotating angles, and specifies a reference position to observe the sample on the basis of the specified rotating angle. The sample position calibrating section relatively rotates the sample in association with the entering direction of the charged particle beam until the reference position is reached.

Embodiments will now be explained with reference to the accompanying drawings. Like components are provided with like reference signs throughout the drawings and repeated descriptions thereof are appropriately omitted. It is to be noted that the accompanying drawings illustrate the invention and assist in the understanding of the illustration and that the shapes, dimensions, and ratios and so on in each of the drawings may be different in some parts from those in an actual apparatus. Moreover, terms indicating directions such as “upper” and “lower” in the explanation show relative directions when a wiring formation side in a given layer on a later-described substrate is set as the top. Therefore, the directions may be different from actual directions based on gravitational acceleration directions.

Hereinafter, there will be described a scanning electron microscope in which an electron beam is used as a charged particle beam, but the present invention is not limited to this example, and needless to say, the present invention is applicable to a microscope in which, for example, an ion beam is used.

(A) Charged Particle Beam Apparatus

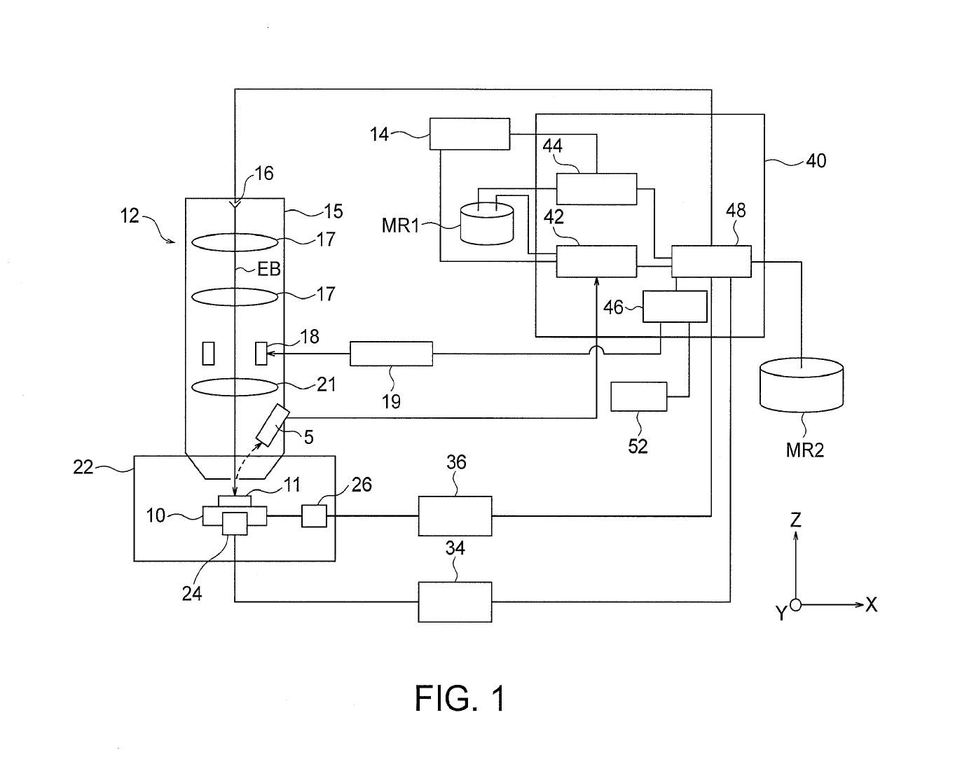

FIG. 1 is one example of a block diagram showing a schematic constitution of a charged particle beam apparatus according to one embodiment. The SEM shown in FIG. 1 includes an electron microscope main body 12, a control computer 40, a scanning control circuit 19, an azimuth angle direction rotation control section 34, a tilt angle direction rotation control section 36, an input device 52, a monitor 14, and memories MR1 and MR2.

The electron microscope main body 12 includes a column 15 and a sample chamber 22.

In the column 15, there are disposed an electron gum 16, condenser lenses 17, a deflector 18, an objective lens 21, and a detector 5.

In the sample chamber 22, there are disposed a stage 10, an azimuth angle direction rotation drive mechanism 24, and a tilt angle direction rotation drive mechanism 26.

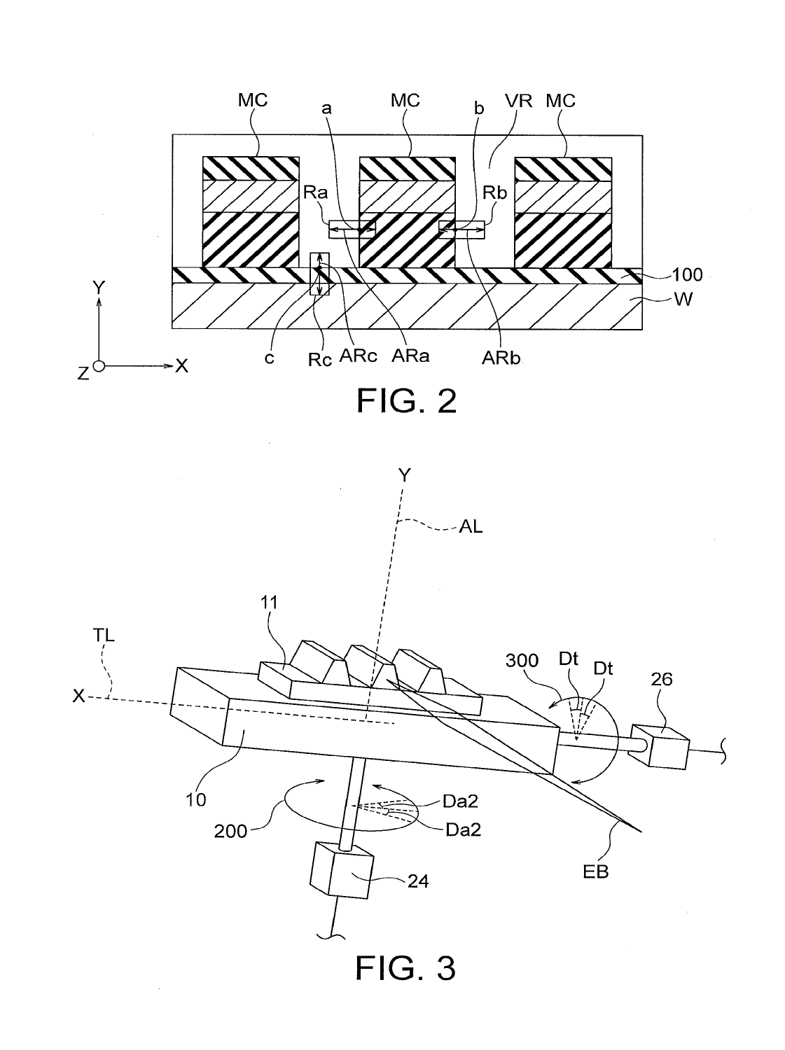

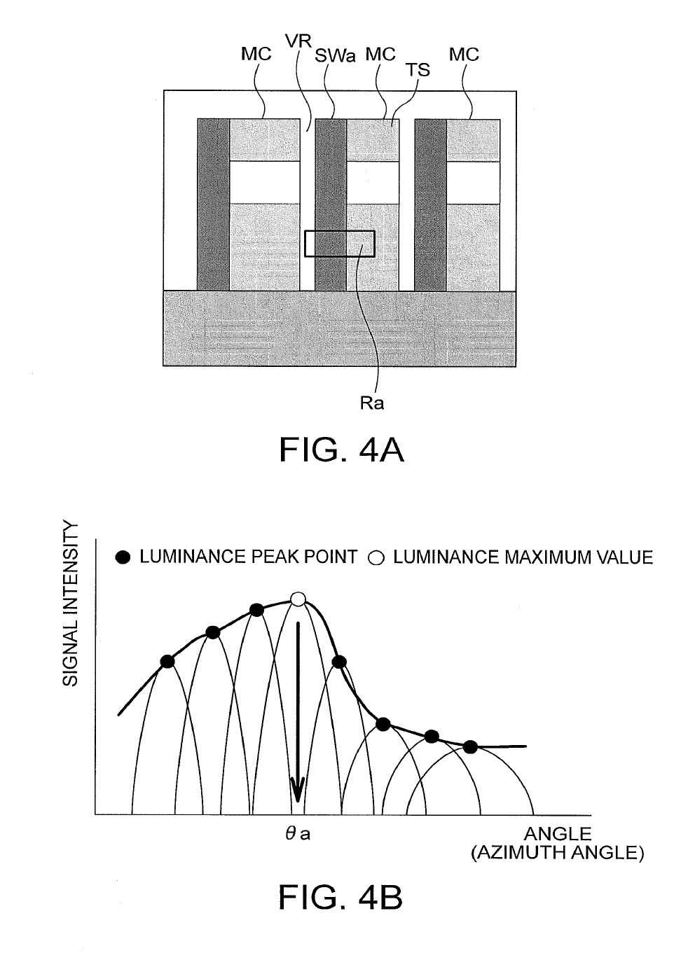

The stage 10 holds a sample 11 in which a structure of an inspection object is formed on a wafer W (see FIG. 2) (see FIG. 3). The stage 10 is movable in an X-direction and a Y-direction by an unshown actuator. Furthermore, the stage 10 is coupled with the tilt angle direction rotation drive mechanism 26 and the azimuth angle direction rotation drive mechanism 24, and is rotatable in each of a tilt angle direction (see reference numeral 300 of FIG. 3) and an azimuth angle direction (see reference numeral 200 of FIG. 3) as shown in FIG. 3.

The control computer 40 corresponds to, for example, a control section in the present embodiment, and includes a signal processing section 42, a zero point specifying section 44, a scanning range setting section 46 and a control signal generating section 48.

The control signal generating section 48 is connected to the electron gun 16, the signal processing section 42, the zero point specifying section 44, the scanning range setting section 46, the azimuth angle direction rotation control section 34, and the tilt angle direction rotation control section 36, and generates various instructing signals to control these devices and circuits.

In the memory MR2, a recipe profile is stored in which a series of procedure of after-mentioned sample position calibration is described, and the control signal generating section 48 extracts the recipe profile from the memory MR2 to perform automatic calibration of a sample position.

The scanning range setting section 46 receives information of an irradiating position corresponding to a desirable edge from the input device 52, and sets scanning ranges (see reference signs Ra to Rc of FIG. 2) of an electron beam EB on the basis of this irradiating position.

The scanning control circuit 19 is connected to the deflector 18 in the column 15.

The azimuth angle direction rotation control section 34 is connected to the azimuth angle direction rotation drive mechanism 24 in the sample chamber 22, and generates a signal to drive the azimuth angle direction rotation drive mechanism 24 on the basis of the instructing signal sent from the control signal generating section 48, thereby sending the signal to the azimuth angle direction rotation drive mechanism 24.

The azimuth angle direction rotation drive mechanism 24 is given a control signal from the azimuth angle direction rotation control section 34 to rotate the stage 10 in the azimuth angle direction 200 (see FIG. 3).

The tilt angle direction rotation control section 36 is connected to the tilt angle direction rotation drive mechanism 26 in the sample chamber 22, and generates a signal to drive the tilt angle direction rotation drive mechanism 26 on the basis of the instructing signal sent from the control signal generating section 48, thereby sending the signal to the tilt angle direction rotation drive mechanism 26.

The tilt angle direction rotation drive mechanism 26 is given the control signal from the tilt angle direction rotation control section 36 to rotate the stage 10 in the tilt angle direction 300 (see FIG. 3).

The electron gun 16 generates the electron beam EB in accordance with the instructing signal sent from the control signal generating section 48 to emit the electron beam EB toward the sample 11. The emitted electron beam EB is condensed by the condenser lens 17 and then, a focal position is adjusted by the objective lens 21 to irradiate the sample 11.

The scanning control circuit 19 generates a deflection control signal on the basis of the instructing signal sent from the scanning range setting section 46. The deflector 18 forms a deflecting electric field or a deflecting magnetic field by the deflection control signal supplied from the scanning control circuit 19, and appropriately deflects the electron beam EB in the X-direction and the Y-direction to scan the surface of the sample 11 with the electron beam EB.

From the surface of the sample 11 irradiated with the electron beam EB, a secondary electron, a reflected electron and a backscattered electron (hereinafter simply referred to as “the secondary electrons and the like”) 3 are generated and detected by the detector 5.

The detector 5 is connected to the signal processing section 42 and a detection signal is sent to the signal processing section 42.

The signal processing section 42 processes the detection signal sent from the detector 5 to generate an image (a SEM image) of the sample surface, stores the image in the memory MR1 and also displays the image in the monitor 14.

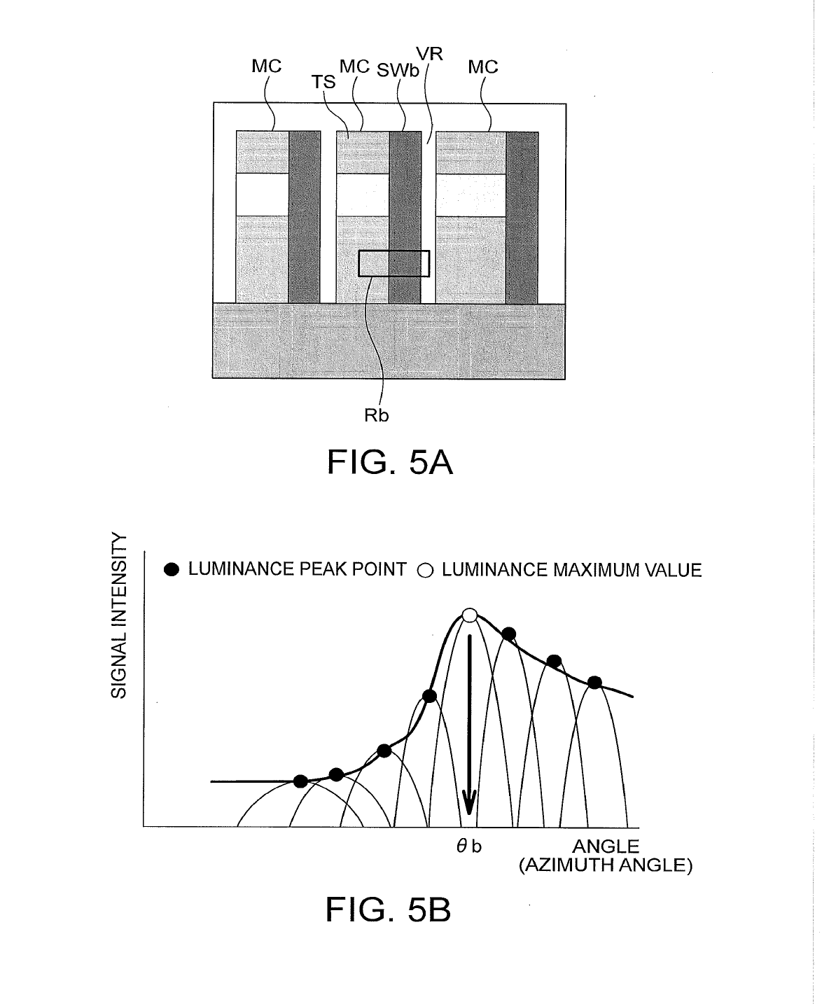

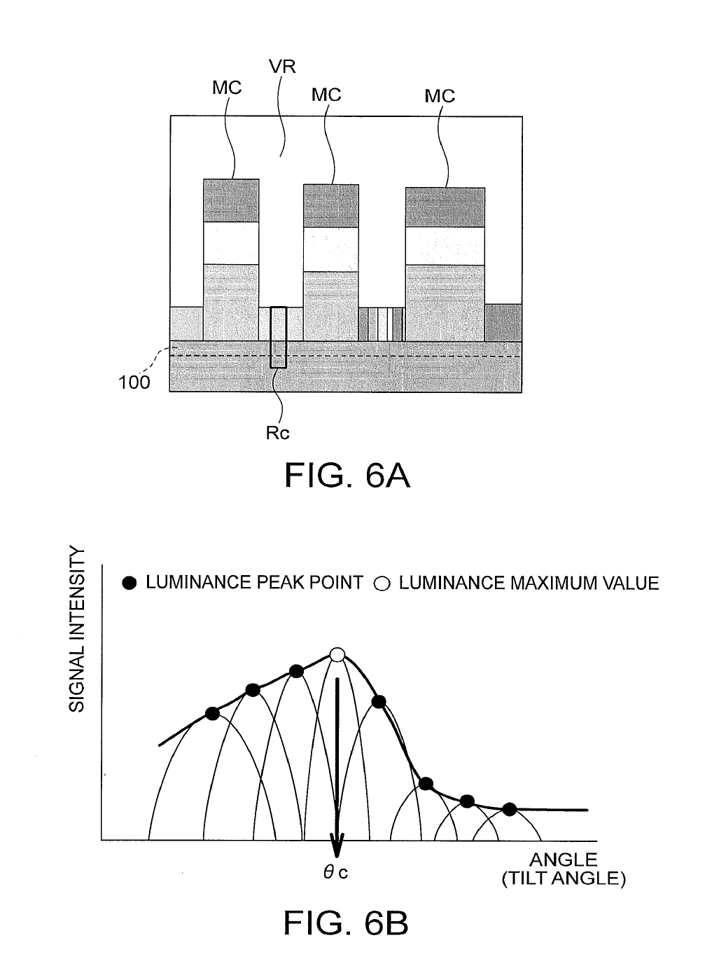

The signal processing section 42 also processes the detection signal sent from the detector 5 to prepare a luminance profile, and stores the profile in the memory MR1 and also displays the profile in the monitor 14. The luminance profile is, for example, a signal waveform chart in which the abscissa indicates a tilt angle or an azimuth angle and the ordinate indicates a signal intensity as shown in FIG. 4B, FIG. 5B and FIG. 6B. The luminance profile is prepared by scanning the sample 11 with the electron beam EB while rotating the stage 10 by every predetermined angle distributed in advance in the tilt angle direction 300 (see FIG. 3) or the azimuth angle direction 200 (see FIG. 3), and processing a signal obtained when the detector 5 detects the secondary electrons and the like 3 generated from the sample 11, by the signal processing section 42 as described later.

The zero point specifying section 44 analyzes the luminance profile prepared by the signal processing section 42 to specify a position (hereinafter referred to as “a zero point”) at which distal side information is minimized in the SEM image. Here, “the distal side information” is information obtained in accordance with the secondary electrons and the like generated from a sample surface other than the sample surface which is an observation object. For example, when a cut surface is the observation object, the information is obtained in accordance with the secondary electrons and the like generated from the sample surface which is continuous with the cut surface and positioned on a distal side of the cut surface seen from an electron gun side (a proximal side of a paper surface), e.g., a side wall (see SWa of FIG. 4A or SWb of FIG. 5A) of a memory cell MC extending on the distal side of the paper surface, a substrate surface or the like in the example shown in FIG. 2. In the present embodiment, the zero point corresponds to, for example, a reference position to observe the sample.

When the zero point is specified by the zero point specifying section 44, the control signal generating section 48 calculates each of a difference between a tilt angle component of the zero point and the present tilt angle of the stage 10 and a difference between an azimuth angle component of the zero point and the present azimuth angle of the stage, and generates signals indicating moving directions and movement amounts to give the signals to the tilt angle direction rotation control section 36 and the azimuth angle direction rotation control section 34.

In the present embodiment, the control signal generating section 48, the tilt angle direction rotation control section 36 and the azimuth angle direction rotation control section 34 correspond to, for example, a sample position calibrating section.

It is to be noted that when the position of the stage 10 may be adjusted in accordance with one of the tilt angle and the azimuth angle depending on the number of the positions to be irradiated with the electron beam, or the like, a difference concerning the required angle between the zero point and the actual position may be calculated, and a signal indicating the moving direction and the movement amount may be generated to be given to the tilt angle direction rotation control section 36 or the azimuth angle direction rotation control section 34.

(B) Method of Calibrating Sample Position

The calibration of the sample position in which the SEM shown in FIG. 1 is used will be described as one embodiment of the method of calibrating the sample position with reference to FIG. 2 to FIG. 6B.

(1) Preparation of Sample and the Like

First, the sample 11 is prepared. The wafer is cut, and processing is performed to expose the structure of the inspection object on the surface by a focused ion beam (FIB) apparatus or the like.

FIG. 2 is one example of a front view showing one example of the sample 11. The example shown in FIG. 2 is one example where a memory device which is being manufactured is processed, and memory cells MCs are disposed at a predetermined interval on a silicon oxide (SiO2) film 100 on the surface of a silicon wafer W.

Here, there is described a case where the position calibration in the azimuth angle direction is performed by two-points irradiation and the position calibration in the tilt angle direction is performed by one-point irradiation.

In the example shown in FIG. 2, for example, two points “a” and “b” on edges of both side walls facing each other are set as irradiating points to measure a width of a bit line direction (not shown) of the memory cell MC.

Furthermore, a scanning direction and the scanning range of the electron beam EB are set on the basis of each irradiating point. In the present embodiment, the scanning ranges Ra and Rb are set in such a manner that the surface can be scanned with the electron beam EB in directions ARa and Arb connecting the two points “a” and “b”.

In addition, one point “c” in the vicinity of an interface between a region VR having a vacuum state when irradiated with the beam and the structure (the silicon oxide (SiO2) film 100 and the silicon wafer W) is set as the irradiating point for the position calibration in the tilt angle direction. Subsequently, the scanning direction and the scanning range of the electron beam EB are set on the basis of the irradiating point “c”. In the present embodiment, the scanning range Rc is set in such a manner that the range can be scanned with the electron beam EB in a direction ARc passing the point “c” and extending perpendicularly to the surface of the silicon wafer W.

The prepared sample 11 is attached to the stage 10. FIG. 3 is one example of a perspective view showing an example where the sample 11 is attached to the stage 10. As shown in FIG. 3, the sample 11 is attached in such a manner that the beam scanning regions (Ra to Rc of FIG. 2) face an electron gun 16 side. In the present embodiment, the sample 11 is positioned and attached in such a manner that the X-direction of FIG. 2 corresponds to an axial line TL of tilt angle rotation and the Y-direction of FIG. 3 corresponds to an axial line AL of azimuth angle rotation.

It is to be noted that, to facilitate understanding, the perspective view of FIG. 3 is drawn in which the electron beam EB enters into the cut surface of the sample 11 obliquely from the proximal side of the paper surface, but the surface is often irradiated with the electron beam EB in a direction of gravitational acceleration (see FIG. 1) or a direction opposite to the gravitational acceleration direction.

When the attaching is finished, the inside of the sample chamber 22 is evacuated by an unshown vacuum pump.

Next, the beam irradiating points and the scanning ranges for the position calibration are set on a three-dimensional coordinate system of a SEM apparatus. Specifically, the electron beam EB is generated from the electron gun 16 to scan the sample 11, thereby once acquiring the SEM image, and by observation of this SEM image, the irradiating points (e.g., “a” to “c” of FIG. 2) and the scanning directions (e.g., ARa to Arc of FIG. 2) are set, and the scanning ranges (e.g., Ra to Rc of FIG. 2) are set by the scanning range setting section 46.

(2) Position Calibration in Azimuth Angle Direction

In the present embodiment, when the position calibration in the azimuth angle direction is performed, the two points “a” and “b” facing each other as shown in FIG. 2 are irradiated, and hence both-sides calibration is performed.

Thus, a midpoint of an open angle between these two points “a” and “b” is obtained to specify the azimuth angle component of the zero point. When the azimuth angle component of the zero point can be specified, a calibrating angle in the azimuth angle from the actual position to the zero point can be calculated, and a calibration amount in the azimuth angle direction 200 (see FIG. 3) can be obtained.

First, there is set a total rotation amount in a case where the stage 10 is rotated around the axial line AL from a default state (the actual sample position) in the azimuth angle direction 200, the total rotation amount is divided by an arbitrary amount to index a rotating angle per scanning (hereinafter, each indexed rotating angle will be referred to as “an indexed angle Da2”), and an operator inputs the angle from the input device 52 into the control signal generating section 48. In the present embodiment, the axial line AL corresponds to, for example, a first axial line.

Next, for each of the irradiating points “a” and “b”, the scanning ranges Ra and Rb of the sample 11 are scanned with the electron beam EB while rotating the stage 10 by each indexed angle Da2 around the axial line AL in the azimuth angle direction 200 to detect the secondary electrons and the like 3 by the detector 5, thereby detecting a position at which a luminance of the secondary electrons and the like 3 is maximized, i.e., a position at which a intensity of the detection signal is maximized. A direction of the rotation may be a clockwise direction or a counterclockwise direction.

The irradiating point “a” will more specifically be described.

The stage 10 is rotated by each indexed angle Da2 in the azimuth angle direction 200 from a position at which the distal side of the memory cell MC is reflected as shown in FIG. 4A (a position at which information from the side wall SWa enters in addition to an original irradiating surface TS) via a position (not shown) at which the reflection of the distal side is eliminated to a position (not shown) at which information from the opposite side wall further enters, by the azimuth angle direction rotation drive mechanism 24. At this time, the scanning range Ra of the sample 11 is scanned by each indexed angle Da2 with the electron beam EB on the basis of the irradiating point “a”. In the present embodiment, the azimuth angle direction rotation drive mechanism 24 corresponds to, for example, a first rotation driving section.

The intensity of the detection signal output from the detector 5 is measured for every beam scanning by the signal processing section 42 to be recorded in the memory MR1, and plotted in a graph in which the abscissa indicates the azimuth angle and the ordinate indicates the signal intensity as shown in, for example, FIG. 4B.

As seen from FIG. 4B, in accordance with the rotation of the stage 10 influences of the secondary electrons and the like 3 to be emitted from the side wall SWa of the memory cell MC are decreased to reduce the distal side information, whereby a peak of the signal intensity gradually heightens, and the signal intensity reaches the maximum peak right before the distal side information disappears. After the distal side information disappears, the peak of the signal intensity lowers. In consequence, it is seen that the azimuth angle component of the zero point may be obtained from the position of the azimuth angle which gives the signal intensity of the maximum peak.

In the SEM shown in FIG. 1, when the beam scanning is performed in all predetermined rotation ranges to obtain a record of the signal intensity, the zero point specifying section 44 takes the record, e.g., such a graph as shown in FIG. 4B from the memory MR1, detects the highest signal intensity from all scanning signal peaks, and specifies the corresponding azimuth angle. Here, the specified azimuth angle is defined as Ba.

Next, also concerning the point “b” in the inspection object region Rb, in the same manner as in the point “a”, the stage 10 is rotated by each indexed angle Da2 in the azimuth angle direction 200 from a position at which the distal side of the memory cell MC is reflected as shown in FIG. 5A (a position at which information from the side wall SWb enters in addition to the original irradiating surface TS) via a position (not shown) at which the reflection of the distal side is eliminated to a position (not shown) at which information from the opposite side wall further enters, by the azimuth angle direction rotation drive mechanism 24. At this time, the scanning range Rb of the sample 11 is scanned by each indexed angle Da2 with the electron beam EB on the basis of the irradiating point “b”. As a direction of the rotation, the stage may rotate oppositely to the abovementioned rotation based on the irradiating point “a”, or a starting point may separately be disposed to rotate the stage in the same direction as the rotating direction based on the irradiating point “a”.

The signal intensity is measured for every beam scanning by the signal processing section 42 to be recorded in the memory MR1, and plotted in a graph in which the abscissa indicates the azimuth angle and the ordinate indicates the signal intensity as shown in, for example, FIG. 5B.

When the beam scanning is performed in all rotation ranges to obtain a record of the signal intensity, the zero point specifying section 44 takes the record, e.g., such a graph as shown in FIG. 5B from the memory MR1, detects the signal peak having the highest signal intensity from all the scanning signal peaks, and specifies the corresponding azimuth angle. The specified azimuth angle is defined as θb.

When the azimuth angles θa and θb each corresponding to the signal peak having the highest signal intensity are obtained at the points “a” and “b”, respectively, an azimuth angle component ZP(azim) of the zero point can be obtained as follows:

ZP(azim)=(θa+θb)/2 Equation (1).

Afterward, data of the obtained azimuth angle component ZP(azim) of the zero point is sent from the zero point specifying section 44 to the control signal generating section 48, the control signal generating section 48 calculates a difference between the azimuth angle of ZP(azim) and the actual azimuth angle of the stage 10, and a signal indicating the moving direction and the movement amount is generated to be given to the azimuth angle direction rotation control section 34. The azimuth angle direction rotation control section 34 generates a control signal to drive the azimuth angle direction rotation drive mechanism 24 in accordance with the signal given from the control signal generating section 48. The azimuth angle direction rotation drive mechanism 24 is given the control signal from the azimuth angle direction rotation control section 34 to rotate the stage 10 as much as the instructed amount in the instructed rotating direction. In consequence, the position calibration (inclination calibration) of the stage 10 in the azimuth angle direction 200 ends.

(3) Position Calibration in Tilt Angle Direction

Next, position calibration in the tilt angle direction is performed. In a sample arrangement shown in FIG. 2 and FIG. 3, one-side calibration is performed in which one point “c” is defined as it is as the irradiating point, and hence, it is sufficient to detect the tilt angle component of the zero point from the point “c”.

First, there is set a total rotation amount in a case where the stage 10 is rotated around the axial line TL from the default state (the actual sample position) in the tilt angle direction 300 (see FIG. 3), the total rotation amount is divided by an arbitrary amount to index a rotating angle per scanning (hereinafter, each indexed rotating angle will be referred to as “an indexed angle Dt”, and the operator inputs the angle from the input device 52 into the control signal generating section 48. In the present embodiment, the axial line TL corresponds to, for example, a second axial line.

Next, the sample 11 is scanned with the electron beam EB while rotating the stage 10 by each indexed angle Dt around the axial line TL in the tilt angle direction 300 by the tilt angle direction rotation drive mechanism 26 to detect the secondary electrons and the like 3, thereby detecting a position at which the luminance of the secondary electrons and the like 3 is maximized, i.e., a position at which the intensity of the detection signal is maximized. A direction of the rotation may be a clockwise direction or a counterclockwise direction. In the present embodiment, the tilt angle direction rotation drive mechanism 26 corresponds to, for example, a second rotation driving section.

Description will more specifically be made with reference to FIG. 3, FIG. 6A and FIG. 6B. For example, the stage 10 is rotated by each indexed angle Dt in the tilt angle direction 300 from a position at which a distal side of the silicon oxide (SiO2) film 100 is reflected as shown in FIG. 6A to a position (not shown) at which the reflection of the distal side is eliminated, by the tilt angle direction rotation drive mechanism 26 (see FIG. 3). The scanning range Rc of the sample 11 is scanned by each indexed angle Dt with the electron beam EB on the basis of the irradiating point “c” (see FIG. 2).

The signal intensity is measured for every scanning by the signal processing section 42 to be recorded in the memory MR1, and plotted in a graph in which the abscissa indicates the tilt angle and the ordinate indicates the signal intensity as shown in, for example, FIG. 6B.

As seen from FIG. 6B, in accordance with the rotation of the stage 10 influences of the secondary electrons and the like 3 to be emitted from the silicon oxide (SiO2) film 100 are decreased to reduce the distal side information, whereby a peak of the signal intensity gradually heightens, and the signal intensity reaches the maximum peak right before the distal side information disappears. After the distal side information disappears, the peak of the signal intensity lowers. In consequence, it is seen that the tilt angle component of the zero point may be obtained from the position of the tilt angle which gives the signal intensity of the maximum peak.

When the beam scanning is performed in all predetermined rotation ranges in the tilt angle direction 300 to obtain a record of the signal intensity, the zero point specifying section 44 takes the record, e.g., such a graph as shown in FIG. 6B from the memory MR1, detects the highest signal intensity from all scanning signal peaks, and specifies the corresponding tilt angle. Here, when the specified tilt angle is defined as θc, regarding the tilt angle direction it is sufficient to take only one point “c” into consideration as described above, the tilt angle component ZP(tilt) of the zero point can thus be obtained as follows:

ZP(tilt)=θc Equation (2).

Subsequently, data of the obtained tilt angle component ZP(tilt) of the zero point is sent from the zero point specifying section 44 to the control signal generating section 48, the control signal generating section 48 calculates a difference between the tilt angle of ZP(tilt) and the actual tilt angle of the stage 10, and a signal indicating the moving direction and the movement amount is generated to be given to the tilt angle direction rotation control section 36.

The tilt angle direction rotation control section 36 generates a control signal to drive the tilt angle direction rotation drive mechanism 26 in accordance with the signal given from the control signal generating section 48.

The tilt angle direction rotation drive mechanism 26 is given the control signal from the tilt angle direction rotation control section 36 to rotate the stage 10 as much as the instructed amount in the instructed rotating direction. In consequence, the position calibration (inclination calibration) of the stage 10 in the tilt angle direction 300 ends.

Afterward, the sample 11 on the stage 10, for which the position calibration is finished, is scanned with the electron beam EB to detect the secondary electrons and the like 3 by the detector 5, and the detection signal is processed by the signal processing section 42 to generate a sample image, thereby performing various measurements such as CD measurement and the like.

In the above description, the calibration in the azimuth angle direction 200 is described as an example of the both-sides calibration, and the calibration in the tilt angle direction 300 is described as an example of the one-side calibration, but the present invention is not limited to the examples, and the one-side calibration or the both-sides calibration can arbitrarily be selected in accordance with the structure of the sample and the manner in which the structure is attached to the stage.

Here, for example, there is considered a case where the position (the tilt) of the stage is being changed while observing the sample image visually by the operator, and at a moment when a boundary of the structure is most clearly seen it is judged that the electron beam enters perpendicularly to the sample and the position at the moment is defined as the zero point, thereby calibrating the stage position. When the sample image tilted as much as, for example, +2° from the zero point visually obtained in this manner is to be photographed, the zero point after the first position (tilt) calibration is ambiguously determined by sensitive adjustment which depends on operator's skill, and hence, even when the image tilted as much as +2° is similarly photographed at a different timing later, the possibility that the same SEM image can be photographed is low.

On the other hand, according to the stage position (tilt) calibration of the abovementioned embodiment, the zero point is specified on the basis of the angle at which the intensity of the secondary electrons and the like from a pattern edge is maximized to automatically calibrate the position (the tilt) of the stage, and hence, a position reproducibility of the zero point is high. The irradiating angle of the electron beam onto the sample has the reproducibility, and hence, a very high reproducibility can be acquired also as to a waveform of the luminance profile by the detection signal of the secondary electrons and the like. In consequence, for example, when the boundary surface of the structure is determined, fluctuations of positioning of the interface can be minimized, and hence, measurement errors caused by the apparatus can be minimized.

According to the charged particle beam apparatus of at least one of the abovementioned embodiments, there is disposed the control computer 40 which specifies the zero point from the azimuth angle and the tilt angle to give the signal intensity of the maximum peak in the luminance profile obtained by scanning the sample with the electron beam EB while rotating the stage 10 by each predetermined angle indexed in advance, whereby the reproducibility can be imparted to the irradiating angle of the electron beam EB onto the sample 11. In consequence, the measurement with high accuracy can be performed.

In addition, according to the method of calibrating the sample position of at least one of the abovementioned embodiments, the zero point is specified from the azimuth angle and the tilt angle to give the signal intensity of the maximum peak in the luminance profile obtained by scanning the sample with the electron beam EB while rotating the stage 10 by each predetermined angle indexed in advance, and the sample 11 is moved until the zero point is reached, so that the reproducibility can be imparted to the irradiating angle of the electron beam EB onto the sample 11. In consequence, the measurement can accurately be performed.

While certain embodiments have been described, these embodiments have been presented by way of example only, and are not intended to limit the scope of the inventions.

For example, in the abovementioned embodiment, the angles to give the signal intensity of the maximum peak as to both of the azimuth angle and the tilt angle are obtained, and from these angles, the zero point is specified. However, only one of the azimuth angle and the tilt angle may be noted in accordance with the structure of the sample and the manner in which the sample is attached to the stage, and the angle which gives the signal intensity of the maximum peak may be obtained.

Indeed, the novel methods and systems described herein may be embodied in a variety of other forms; furthermore, various omissions, substitutions and changes in the form of the methods and systems described herein may be made without departing from the sprit of the inventions. The accompanying claims and their equivalents are intended to cover such forms or modifications as would fall within the scope and spirit of the inventions.

1. A charged particle beam apparatus comprising:
an irradiating section configured to irradiate a sample with a charged particle beam;
a detecting section configured to output a signal corresponding to charged particles generated from the sample;
a range setting section configured to set a scanning range of the charged particle beam;
a scanning control section configured to scan the set scanning range with the charged particle beam;
a control section which relatively rotates the sample by each predetermined unit in association with an entering direction of the charged particle beam, detects a peak value of the signal from the detecting section when the scanning range is scanned by each rotating angle with the charged particle beam, specifies the rotating angle corresponding to the maximum peak value among the peak values of the respective detected rotating angles, and specifies a reference position to observe the sample on the basis of the specified rotating angle; and
a sample position calibrating section configured to relatively rotate the sample in association with the entering direction of the charged particle beam until the reference position is reached.

2. The apparatus of claim 1,
wherein the range setting section sets a plurality of scanning ranges to include a plurality of positions in the sample, respectively, and
the control section obtains the rotating angle corresponding to the maximum peak value in each scanning range, and specifies the reference position on the basis of the plurality of obtained rotating angles.

3. The apparatus of claim 1, further comprising:
a stage which is rotatable around each of a first axial line on a plane orthogonal to the entering direction of the charged particle beam into the sample, and a second axial line crossing the first axial line on the plane,
wherein the control section obtains the rotating angle corresponding to the maximum peak value for each of the first and second axial lines.

4. The apparatus of claim 3,
wherein the first axial line is orthogonal to the second axial line.

5. The apparatus of claim 1,
wherein the range setting section sets the scanning range to include a boundary region between different materials in the sample.

6. A method of calibrating a sample position, comprising:
setting a scanning range of a charged particle beam;
irradiating a sample with the charged particle beam;
detecting charged particles generated from the sample to acquire a signal;
relatively rotating the sample by each predetermined unit in association with an entering direction of the charged particle beam into the sample, and scanning the scanning range by each rotating angle with the charged particle beam;
comparing intensities of the signals obtained by each predetermined angle with each other, thereby specifying a reference position to observe the sample; and
relatively rotating the sample in association with the entering direction of the charged particle beam until the reference position is reached.

7. The method of claim 6,
wherein the reference position is specified on the basis of the rotating angle corresponding to the maximum peak value in the obtained signals.

8. The method of claim 7,
wherein the scanning range comprises a plurality of irradiating points facing each other,
the rotating angle corresponding to the maximum peak value is obtained for each of the irradiating points, and
the reference position is specified on the basis of the plurality of the obtained rotating angles.

9. The method of claim 7,
wherein the sample is rotated around at least one of a first axial line on a plane orthogonal to the entering direction of the charged particle beam into the sample, and a second axial line crossing the first axial line on the plane, and
the rotating angle corresponding to the maximum peak value is obtained for each of the first and second axial lines.

10. The method of claim 9,
wherein the first axial line is orthogonal to the second axial line.

11. The method of claim 6,
wherein the scanning range is set so as to comprise a boundary region between different materials in the sample.
